(19) United States
(12) Patent Application Publication
(10) Pub. No.: US 2012/0235196 A1
(43) Pub. Date: Sep. 20, 2012

(54) LIGHT EMITTING DEVICE AND PROJECTOR

(75) Inventor: Masamitsu MOCHIZUKI, Fujimi (JP)

(73) Assignee: SEIKO EPSON CORPORATION, Tokyo (JP)

(21) Appl. No.: 13/406,571

(22) Filed: Feb. 28, 2012

(30) Foreign Application Priority Data
Mar. 17, 2011 (JP) 2011-059046

(51) Int. Cl. H01L 33/60

(52) U.S. Cl. 257/98; 257/E33.06

(57) ABSTRACT

A light emitting device includes a first layer that generates light by injection current and forms a waveguide for the light, and an electrode that injects the current into the first layer, wherein the waveguide of the light has a first region, a second region, a third region, and a fourth region, the first region and the second region are connected at a first reflection part, the first region and the third region are connected at a second reflection part, the second region and the third region are tilted at the same angle and connected to an output surface, a distance between the fourth region and at least one of the first region, the second region, and the third region is a distance that produces evanescent coupling, and the fourth region forms a resonator.

### BACKGROUND

1. Technical Field

The present invention relates to a light emitting device and a projector.

2. Related Art

A super luminescent diode (hereinafter, also referred to as “SLD”) is a semiconductor light emitting device that can output several hundreds of milliwatts similar to a semiconductor laser, while exhibiting a broadband spectrum and thus being incoherent similar to a typical light emitting diode.

An SLD is sometimes used as a light source of a projector. To realize a small and high-brightness projector, it is necessary to use a light source having high light output and small etendue. For the purpose, it is desirable that light output from plural gain regions travel in the same direction. In Patent Document 1 (JP-A-2010-3833), by combining a gain region having a linear shape and a gain region having a flexed shape via a reflection surface, light output from light output parts (light emitting areas) of the two gain regions travel in the same direction.

To reduce loss of an optical system and reduce the number of optical components, a projector that can perform light collimation and uniform illumination simultaneously by providing a light emitting device immediately below a light valve and using a lens array, has been proposed. In this type of projector, however, it is necessary to provide light output parts according to intervals of the lens array.

In the technology described in Patent Document 1, it is difficult to arrange plural light output parts at distances according to various lens arrays with different intervals, and the technology is not applicable to the projector of the above described type.

### SUMMARY

An advantage of some aspects of the invention is to provide a light emitting device that may be applied to a projector in which distances between plural light output parts may be made larger and a light emitting device is provided immediately below a light valve. Further, an advantage of some aspects of the invention is to provide a projector having the light emitting device.

A light emitting device according to an aspect of the invention includes a first layer that generates light by injection current and forms a waveguide for the light, a second layer and a third layer that sandwich the first layer and suppress leakage of the light, and an electrode that injects the current into the first layer, wherein the waveguide has a first region having a belt-like linear shape, a belt-like second region, a belt-like third region, and a belt-like fourth region, the first region and the second region are connected at a first reflection part provided on a first side surface of the first layer, the first region and the third region are connected at a second reflection part provided on a second side surface of the first layer different from the first side surface, the second region and the third region are connected to a third side surface of the first layer which is an output surface that is different from the first and second side surface, a longitudinal direction of the first region is parallel to the output surface, the second region and the third region are tilted at the same angle and connected to the third side surface as seen from a stacking direction of the first layer, and the second layer, a distance between the fourth region and at least one of the first region, the second region, and the third region is a distance that produces evanescent coupling, and the fourth region forms a resonator.

According to the light emitting device, the first region is provided parallel to the output surface. Accordingly, for example, as compared to the case where the first region is not parallel to the output surface, for example, distances between light output parts provided on the output surface may be made larger without increasing the total length of the first region, the second region, and the third region. That is, the distances between the light output parts may be made larger while the device lengths in the direction perpendicular to the light output surface are made smaller. Thereby, downsizing of the entire device may be realized, and thus resources are not wasted and the manufacturing cost may be suppressed.

Further, according to the light emitting device, the fourth region is formed separately from at least one of the first region, the second region, and the third region at the distance that produces evanescent coupling. Accordingly, the light generated in the fourth region may be output from the light output parts, and intensity of light emitted from the light emitting device may increase. Furthermore, the fourth region may form a resonator. Accordingly, the light emitting device may output light including an SLD light component and a resonant light component as output light. Therefore, speckle noise may be reduced compared to a semiconductor laser while output power increases compared to an ordinary SLD.

A light emitting device according to another aspect of the invention includes a first layer that generates light by injection current and forms a waveguide for the light, a second layer and a third layer that sandwich the first layer and suppress leakage of the light, and an electrode that injects the current into the first layer, wherein the waveguide has a first region having a belt-like linear shape, a belt-like second region, a belt-like third region, and a belt-like fourth region, the first region and the second region are connected at a first reflection part provided on a first side surface of the first layer, the first region and the third region are connected at a second reflection part provided on a second side surface of the first layer different from the first side surface, the second region and the third region are connected to a third side surface of the first layer which is an output surface that is different from the first and second side surface, a longitudinal direction of the first region is parallel to the output surface, an antireflection film that reduces reflectance is formed on the output surface in a wavelength range of the light generated in the first layer, a first light output from the second region at the output surface and a second light output from the third region at the output surface are output parallel to one another, a distance between the fourth region and at least one of the first region, the second region, and the third region is a distance that produces evanescent coupling, and the fourth region forms a resonator.

According to the light emitting device, distances between the plural light output parts may be made larger.

In the light emitting device according to the aspect of the invention, reflection surfaces may be formed at ends of a longitudinal direction of the fourth region.

According to the light emitting device, the fourth region may form a Fabry-Perot resonator, and may reduce the speckle noise enough even when the output light contain the resonant light component.

In the light emitting device according to the aspect of the invention, a periodic structure forming a distributed feedback (DFB) resonator may be formed in the fourth region.

According to the light emitting device, the fourth region may form the DFB resonator, and provide a better light confinement (a longer lifetime of resonance). As a result, light loss may be suppressed.

In the light emitting device according to the aspect of the invention, distributed Bragg reflector (DBR) resonators may be formed at ends of the longitudinal direction of the fourth region.

According to the light emitting device, the fourth region may form the DBR resonators, and speckle noise may be reduced enough while light loss is suppressed.

In the light emitting device according to the aspect of the invention, the longitudinal direction of the first region and the longitudinal direction of the fourth region may be parallel, and the distance between the first region and the fourth region may be a distance that produces evanescent coupling.

According to the light emitting device, evanescent coupling may efficiently be produced between the first region and the fourth region.

In the light emitting device according to the aspect of the invention, the distance between the first region and the fourth region may be from 100 nm to 40 μm.

According to the light emitting device, evanescent coupling may efficiently be produced between the first region and the fourth region.

In the light emitting device according to the aspect of the invention, a plurality of the fourth regions may be provided.

According to the light emitting device, intensity of light emitted from the device may increase.

In the light emitting device according to the aspect of the invention, the distance between the adjacent fourth regions may be from 100 nm to 40 μm.

According to the light emitting device, evanescent coupling may efficiently be produced between the adjacent fourth regions.

In the light emitting device according to the aspect of the invention, the first region, the second region, the third region, and the fourth region may have index guiding type structures.

According to the light emitting device, compared to the case having a gain-guiding type structure, guiding loss of coupled light in the respective regions may be suppressed.

According to still another aspect of the invention, a light emitting device includes a multilayered structure having a first layer, and second layer and third layers that sandwich the first layer; the first layer has a first gain region, a second gain region, a third gain region, and a fourth gain region that generate and guide light, the second layer and the third layer are layers that suppress leakage of the light generated in the first gain region, the second gain region, the third gain region, and the fourth gain region; the first layer has a first surface, a second surface, and a third surface forming an outer shape of the multilayered structure; a reflectance of the first surface is lower than a reflectance of the second surface and a reflectance of the third surface in a wavelength range of the light generated in the first layer; the first gain region is provided parallel to the first surface and providing from the second surface to the third surface as seen from a stacking direction of the multilayered structure, the second gain region overlaps the first gain region on the second surface and is provided from the second surface to the first surface, the third gain region overlaps the first gain region on the third surface and is provided from the third surface to the first surface, the second gain region and the third gain region are separated from each other and tilted at the same angle and connected to the first surface as seen from the stacking direction of the multilayered structure, a distance between the fourth gain region and at least one of the first gain region, the second gain region, and the third gain region is a distance that produces evanescent coupling, and the fourth gain region forms a resonator.

According to the light emitting device, the distances between the light output parts may be made larger.

A projector according to yet another aspect of the invention includes the light emitting device according to the aspect of the invention, a light modulation device that modulates light output from the light emitting device in response to image information, and a projection device that projects an image formed by the light modulation device.

According to the projector, alignment of the lens array may be easy and the light modulation device (such as liquid crystal light valve) may be irradiated with good uniformity.

### BRIEF DESCRIPTION OF THE DRAWINGS

The invention will be described with reference to the accompanying drawings, wherein like numbers reference like elements.

FIG. 1 is a plan view schematically showing a light emitting device according to an embodiment.

FIG. 2 is a sectional view schematically showing the light emitting device according to the embodiment.

FIG. 3 is a sectional view schematically showing the light emitting device according to the embodiment.

FIG. 4 schematically shows the intensity of the light emitted from the light emitting device according to the embodiment.

FIG. 5 is a sectional view schematically showing a manufacturing process of the light emitting device according to the embodiment.

FIG. 6 is a sectional view schematically showing a manufacturing process of the light emitting device according to the embodiment.

FIG. 7 is a sectional view schematically showing a manufacturing process of the light emitting device according to the embodiment.

FIG. 8 is a plan view schematically showing a light emitting device according to a first modified example of the embodiment.

FIG. 9 is a sectional view schematically showing the light emitting device according to the first modified example of the embodiment.

FIG. 10 is a plan view schematically showing a light emitting device according to a second modified example of the embodiment.

FIG. 11 is a sectional view schematically showing the light emitting device according to the second modified example of the embodiment.

FIG. 12 schematically shows light output intensity of light output from the light emitting device according to the second modified example of the embodiment.

FIG. 13 is a plan view schematically showing a light emitting device according to a third modified example of the embodiment.

FIG. 14 is a sectional view schematically showing the light emitting device according to the third modified example of the embodiment.

FIG. 15 schematically shows light output intensity of light output from the light emitting device according to the third modified example of the embodiment.

FIG. 16 is a plan view schematically showing a light emitting device according to a fourth modified example of the embodiment.

FIG. 17 is a sectional view schematically showing the light emitting device according to the fourth modified example of the embodiment.

FIG. 18 is a plan view schematically showing a light emitting device according to a fifth modified example of the embodiment.

FIG. 19 schematically shows a projector according to the embodiment.

FIG. 20 schematically shows the projector according to the embodiment.

FIG. 21 schematically shows a light source of the projector according to the embodiment.

FIG. 22 is a sectional view schematically showing the light source of the projector according to the embodiment.

FIG. 23 is a sectional view schematically showing the light source of the projector according to the embodiment.

FIG. 24 is a sectional view schematically showing the light source of the projector according to the embodiment.

### DESCRIPTION OF EXEMPLARY EMBODIMENTS

Below, a preferred embodiment of the invention will be explained with reference to the drawings.

### 1. Light Emitting Device

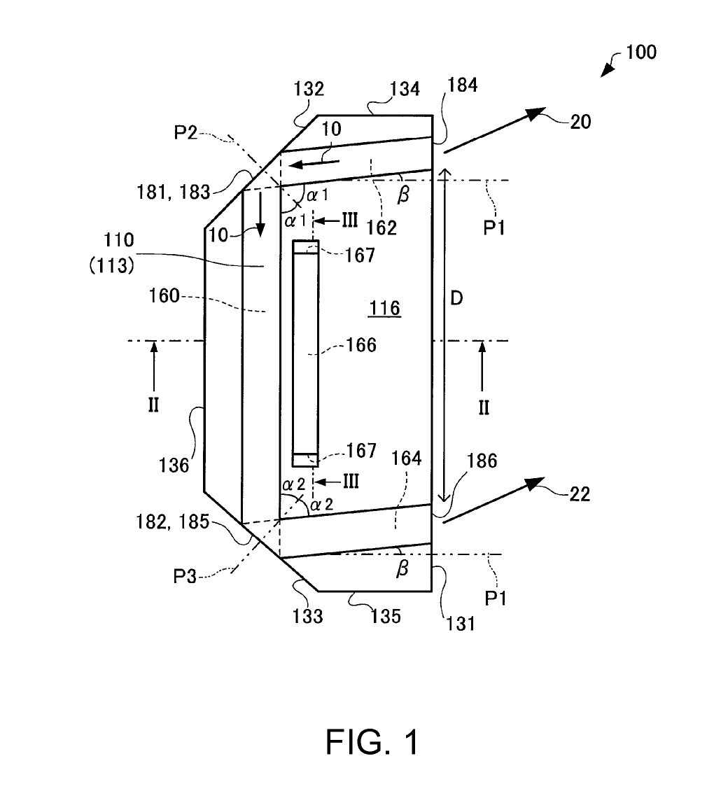

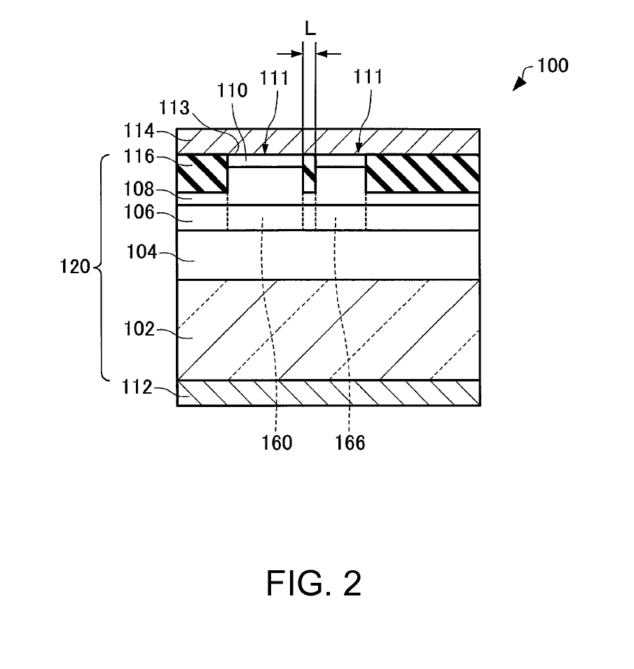

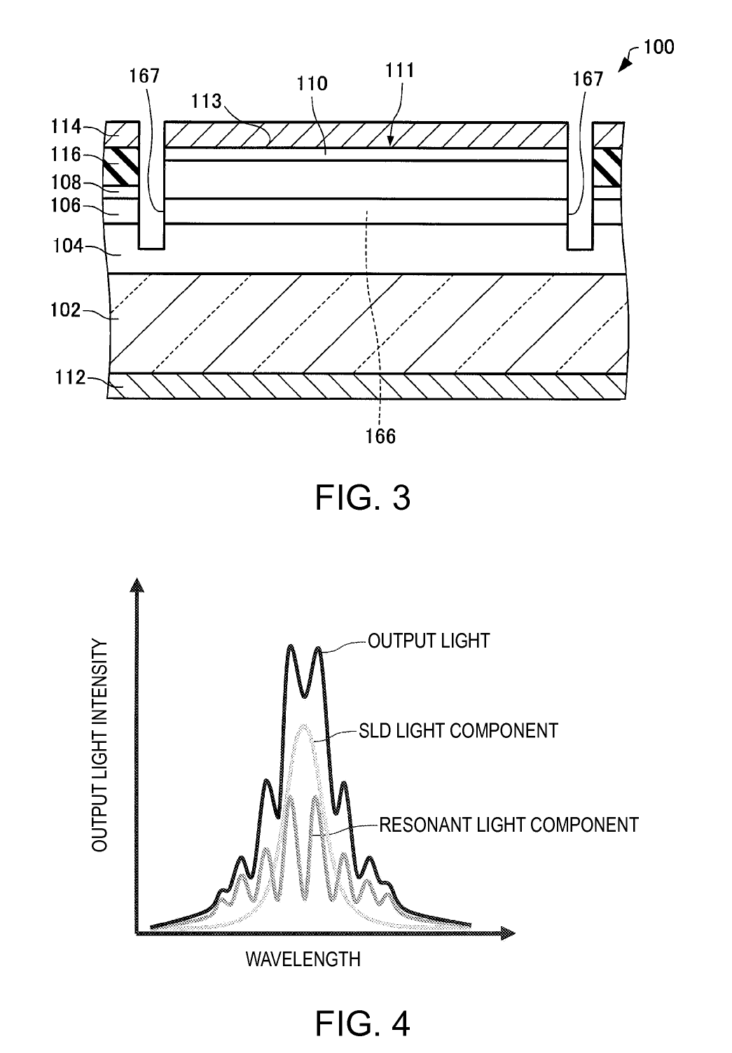

First, a light emitting device according to the embodiment will be explained with reference to the drawings. FIG. 1 is a plan view schematically showing a light emitting device 100 according to the embodiment. FIG. 2 is a sectional view along II-II line of FIG. 1 schematically showing the light emitting device 100 according to the embodiment. FIG. 3 is a sectional view along line of FIG. 1 schematically showing the light emitting device 100 according to the embodiment. Note that, in FIG. 1, for convenience, an illustration of a second electrode 114 is omitted.

As below, the case where the light emitting device 100 is a light source of an InGaAlP system (red) will be explained.

As shown in FIGS. 1 to 3, the light emitting device 100 may include a multilayered structure 120, a first electrode 112, and the second electrode 114.

The multilayered structure 120 may have a substrate 102, a second layer 104 (also referred to as “first cladding layer 104”), a first layer 106 (also referred to as “active layer 106”), a third layer 108 (also referred to as “second cladding layer 108”), a contact layer 110, and an insulating layer 116.

As the substrate 102, for example, a first conductivity-type (for example, n-type) GaAs substrate or the like may be used.

The first cladding layer 104 is formed on the substrate 102. As the first cladding layer 104, for example, an n-type InGaAlp layer or the like may be used. Note that, though not illustrated, a buffer layer may be formed between the substrate 102 and the first cladding layer 104. As the buffer layer, for example, an n-type GaAs layer, AlGaAs layer, InGaP layer, or the like may be used. The buffer layer may improve crystal quality of layers formed thereon.

The active layer 106 is formed on the first cladding layer 104. The active layer 106 is sandwiched between the first cladding layer 104 and the second cladding layer 108. The active layer 106 has a multiple quantum well (MQW) structure in which three quantum well structures each including an InGaP well layer and an InGaAlP barrier layer, for example, are stacked.

The planar shape of the active layer 106 is the same as the planar shape of the multilayered structure 120, for example. In the example shown in FIG. 1, the planar shape of the active layer 106 is a hexagonal shape and has a first surface 131, a second surface 132, a third surface 133, a fourth surface 134, a fifth surface 135, and a sixth surface 136. The surfaces 131 to 136 are the surfaces of the active layer 106, do not have in plane contact with the first cladding layer 104 and the second cladding layer 108, and form an outer shape of the multilayered structure 120. The surfaces 131 to 136 are flat surfaces provided on the side surfaces (side walls) of the active layer 106 as seen from the stacking direction of the multilayered structure 120.

In the example shown in FIG. 1, the surfaces 134, 135 are orthogonal to the surface 131. The surface 136 is opposed to the surface 131. The surface 132 is connected to the surfaces 134, 136 and tilted with respect to the surface 131. The surface 133 is connected to the surfaces 135, 136 and tilted with respect to the surface 131. For example, the surfaces 131, 134, 135, 136 are formed by cleavage and the surfaces 132, 133 are formed by etching.

Parts of the active layer 106 form a first gain region 160, a second gain region 162, a third gain region 164, and a fourth gain region 166. The gain regions 160, 162, 164, 166 may generate light and the light may be amplified while propagating through the gain regions 160, 162, 164, 166. That is, the gain regions 160, 162, 164, 166 also serve as waveguides for the light generated in the active layer 106.

The first gain region 160 has a belt-like linear longitudinal shape having a predetermined width (a shape having a longitudinal direction and a shorter direction) in a plan view from the stacking direction of the multilayered structure 120 as shown in FIG. 1. Further, as seen from the stacking direction of the multilayered structure 120 (in the plan view), the first gain region 160 is provided so that its longitudinal direction from the second surface 132 toward the third surface 133 may be parallel to the first surface 131. The first gain region 160 has a first end surface 181 provided on the second surface 132 and a second end surface 182 provided on the third surface 133.

Note that “the longitudinal direction of the first gain region 160” is an extension direction of a straight line passing through the center of the first end surface 181 and the center of the second end surface 182 in the plan view from the stacking direction of the multilayered structure 120, for example. Further, the longitudinal direction may be an extension direction of a boundary line of the first gain region 160 (and the part except the first gain region 160).

Further, “the first gain region 160 is parallel to the first surface 131” means that the tilt angle of the first gain region 160 with respect to the first surface 131 is within ±1° in the plan view in consideration of manufacturing variations.

The first gain region 160 is connected to the second surface 132 tilted at a first angle α1 with respect to a perpendicular line P2 of the second surface 132 in the plan view from the stacking direction of the multilayered structure 120. In other words, the longitudinal direction of the belt-like shape of the first gain region 160 has the angle α1 with respect to the perpendicular line P2. Further, the first gain region 160 is connected to the third surface 133 tilted at a second angle α2 with respect to a perpendicular line P3 of the third surface 133. In other words, the longitudinal direction of the belt-like shape of the first gain region 160 has the angle α2 with respect to the perpendicular line P3.

The length of the first gain region 160 is larger than the length of the second gain region 162 and the length of the third gain region 164. The length of the first gain region 160 may be equal to or more than the sum of the lengths of the second gain region 162 and the third gain region 164. Note that “the length of the first gain region 160” is also a distance between the center of the first end surface 181 and the center of the second end surface 182. Regarding the other gain regions, similarly, the length is also a distance between the centers of two end surfaces.

The second gain region 162 has, for example, a belt-like linear longitudinal shape having a predetermined width from the second surface 132 to the first surface 131 in the plan view from the stacking direction of the multilayered structure 120. The second gain region 162 has a third end surface 183 provided on the second surface 132 and a fourth end surface 184 provided on the first surface 131.

Note that “the longitudinal direction of the second gain region 162” is an extension direction of a straight line passing through the center of the third end surface 183 and the center of the fourth end surface 184 in the plan view from the stacking direction of the multilayered structure 120, for example. Further, the longitudinal direction may be an extension direction of a boundary line of the second gain region 162 (and the part except the second gain region 162).

The third end surface 183 of the second gain region 162 overlaps with the first end surface 181 of the first gain region 160 on the second surface 132. In the illustrated example, the first end surface 181 and the third end surface 183 completely overlap.

The second gain region 162 is connected to the second surface 132 tilted at the first angle α1 with respect to the perpendicular line P2 in the plan view from the stacking direction of the multilayered structure 120. In other words, the longitudinal direction of the second gain region 162 has the angle α1 with respect to the perpendicular line P2. That is, the angle of the first gain region 160 with respect to the perpendicular line P2 and the angle of the second gain region 162 with respect to the perpendicular line P2 are the same in the range of manufacturing variations. The first angle α1 is an acute angle and equal to or more than the critical angle. Thereby, the second surface 132 may totally reflect the light generated in the gain regions 160, 162, 164, 166.

Note that “the angle of the first gain region 160 with respect to the perpendicular line P2 and the angle of the second gain region 162 with respect to the perpendicular line P2 are the same” means that they have an angle difference within about ±2°, for example, in consideration of manufacturing variations of etching or the like.

The second gain region 162 is connected to the first surface 131 tilted at an angle β with respect to a perpendicular line P1 of the first surface 131 in the plan view from the stacking direction of the multilayered structure 120. In other words, the longitudinal direction of the second gain region 162 has the angle β with respect to the perpendicular line P1. The angle β is an acute angle less than the critical angle.

The third gain region 164 has, for example, a belt-like linear longitudinal shape having a predetermined width from the third surface 133 to the first surface 131 in the plan view from the stacking direction of the multilayered structure 120. That is, the third gain region 164 has a fifth end surface 185 provided on the third surface 133 and a sixth end surface 186 provided on to the first surface 131.

Note that “the longitudinal direction of the third gain region 164” is an extension direction of a straight line passing through the center of the fifth end surface 185 and the center of the sixth end surface 186 in the plan view from the stacking direction of the multilayered structure 120, for example. Further, the longitudinal direction may be an extension direction of a boundary line of the third gain region 164 (and the part except the third gain region 164).

The fifth end surface 185 of the third gain region 164 overlaps with the second end surface 182 of the first gain region 160 on the third surface 133. In the illustrated example, the second end surface 182 and the fifth end surface 185 completely overlap.

The second gain region 162 and the third gain region 164 are separated from each other. In the example shown in FIG. 1, the fourth end surface 184 of the second gain region 162 and the sixth end surface 186 of the third gain region 164 are separated at a distance D.

The third gain region 164 is connected to the third surface 133 tilted at the second angle α2 with respect to the perpendicular line P3 in the plan view from the stacking direction of the multilayered structure 120. In other words, the longitudinal direction of the third gain region 164 has the angle α2 with respect to the perpendicular line P3. That is, the angle of the first gain region 160 with respect to the perpendicular line P3 and the angle of the third gain region 164 with respect to the perpendicular line P3 are the same in the range of manufacturing variations. The second angle α2 is an acute angle and equal to or more than the critical angle. Thereby, the third surface 133 may totally reflect the light generated in the gain regions 160, 162, 164, 166.

Note that “the angle of the first gain region 160 with respect to the perpendicular line P3 and the angle of the third gain region 164 with respect to the perpendicular line P3 are the same” means that they have an angle difference within about ±2°, for example, in consideration of manufacturing variations of etching or the like.

The third gain region 164 is connected to the first surface 131 tilted at the angle β with respect to the perpendicular line P1 in the plan view from the stacking direction of the multilayered structure 120. In other words, the longitudinal direction of the third gain region 164 has the angle β with respect to the perpendicular line P1. That is, the second gain region 162 and the third gain region 164 are connected to the first surface 131 and tilted at the same angle so as to be parallel to each other in plan view. More specifically, the longitudinal direction of the second gain region 162 and the longitudinal direction of the third gain region 164 are parallel to each other. Thereby, a light 20 output from the fourth end surface 184 and a light 22 output from the sixth end surface 186 may travel in the same direction. The end surfaces 184, 186 may serve as light output parts (light emitting areas).

The angle β may be set to an angle larger than 0°. Thereby, it may be possible to prevent direct multiple reflections of the light generated in the gain regions 160, 162, 164 between the fourth end surface 184 and the sixth end surface 186. As a result, it may be possible to prevent formation of a direct resonator in the gain regions 160, 162, 164.

As described above, by setting the angles α1, α2 equal to or more than the critical angle and the angle β less than the critical angle, reflectance of the first surface 131 may be made lower than reflectance of the second surface 132 and reflectance of the third surface 133. That is, the first surface 131 may serve as a light output surface and the fourth end surface 184 and the sixth end surface 186 provided on the output surface may serve as light output parts (light output parts 184, 186: light emitting areas) that output light generated in the gain regions 160, 162, 164, 166. The second surface 132 and the third surface 133 may serve as reflection surfaces and the first end surface 181 and the third end surface 183 provided on the reflection surface may serve as first reflection parts (first reflection parts 181, 183: first reflection areas) that reflect the light generated in the gain regions 160, 162, 164, 166. Similarly, the second end surface 182 and the fifth end surface 185 provided on the reflection surface may serve as second reflection parts (second reflection parts 182, 185: second reflection areas) that reflect the light generated in the gain regions 160, 162, 164, 166.

Note that, though not illustrated, for example, the first surface 131 may be covered by an antireflection film and the second surface 132 and the third surface 133 may be covered by reflection films. Thereby, even when incident angles, refractive indices, and the like may not satisfy the total reflection condition, the reflectance of the first surface 131 in the wavelength band of the light generated in the gain regions 160, 162, 164, 166 may be made lower than that of the second surface 132 and the third surface 133. Further, since the first surface 131 is covered by the antireflection film, direct multiple reflection of the light generated in the gain regions 160, 162, 164, 166 between the fourth end surface 184 and the sixth end surface 186 may considerably be reduced.

As the reflection film and the antireflection film, SiO₂ layers, Ta₂O₅ layers, Al₂O₃ layers, TiN layers, TiO₂ layers, SiON layers, SiN layers, multilayer films of them, or the like may be used. Further, higher reflectance may be obtained using DBR (Distributed Bragg Reflector) formed by etching the part of the multilayered structure 120 outside the surfaces 132, 133.

The fourth gain region 166 has a belt-like linear longitudinal shape having a predetermined width, for example, in the plan view from the stacking direction of the multilayered structure 120 as shown in FIG. 1. The fourth gain region 166 is provided separately from at least one of the gain regions 160, 162, 164 at a distance that produces evanescent coupling. In the example shown in FIG. 2, the fourth gain region 166 is surrounded by the first gain region 160, the second gain region 162, the third gain region 164, and the first surface 131 in the plan view from the stacking direction of the multilayered structure 120, and a distance L (see FIG. 2) between the first gain region 160 and the fourth gain region 166 is a distance that produces evanescent coupling. The distance L depends on the refractive indices and the waveguide widths (widths in the shorter direction) of the first gain region 160 and the fourth gain region 166, and is from 100 nm to 40 μm, for example. The longitudinal direction of the first gain region 160 and the longitudinal direction of the fourth gain region 166 are in parallel, for example. Further, it is desirable that the distance L between the first gain region 160 and the fourth gain region 166 is equal to or shorter than the waveguide widths of the first gain region 160 and the fourth gain region 166.

Reflection surfaces 167 are formed at ends of the longitudinal direction of the fourth gain region 166. The reflection surface 167 may be one surface of an opening part formed by etching part of the multilayered structure 120, for example. The opening part may penetrate the active layer 106 as shown in FIG. 3. In the illustrated example, the bottom surface of the opening part is located between the upper surface and the lower surface of the first cladding layer 104.

Note that “the longitudinal direction of the fourth gain region 166” is an extension direction of a straight line passing through the centers of the two reflection surfaces 167 in the plan view from the stacking direction of the multilayered structure 120, for example. Further, the longitudinal direction may be an extension direction of a boundary line of the fourth gain region 166 (and the part except the fourth gain region 166).

The second cladding layer 108 is formed on the active layer 106 as shown in FIG. 2. As the second cladding layer 108, for example, a second conductivity-type (for example, p-type) InGaAlP layer or the like may be used.

For example, the p-type second cladding layer 108, the active layer 106 not doped with impurity, and the n-type first cladding layer 104 form a pin diode. Each of the first cladding layer 104 and the second cladding layer 108 is a layer having a larger forbidden band gap and a lower refractive index than those of the active layer 106. The active layer 106 has a function of generating light and amplifying and guiding the light. The first cladding layer 104 and the second cladding layer 108 sandwich the active layer 106 and have a function of confining injected carriers (electrons and holes) and light (suppressing leakage of light).

In the light emitting device 100, when a forward bias voltage of the pin diode is applied between the first electrode 112 and the second electrode 114 (when a current is injected), the gain regions 160, 162, 164, 166 are produced in the active layer 106 and recombination of electrons and holes occurs in the gain regions 160, 162, 164, 166. Light is generated by the recombination. Starting from the generated light, stimulated emission occurs and the intensity of the light is amplified within the gain regions 160, 162, 164, 166.

For example, as shown in FIG. 1, the light generated in the second gain region 162 and traveling toward the second surface 132 side is amplified within the second gain region 162, and then reflected by the second surface 132 (end surfaces 181, 183) and travels in the first gain region 160 toward the third surface 133. Then, the light is further reflected by the third surface 133 (end surfaces 182, 185), travels through the third gain region 164, and is output from the sixth end surface 186 as the output light 22. Concurrently, the intensity of the light is also amplified within the gain regions 160, 164. Similarly, the light generated in the third gain region 164 and traveling toward the third end surface 133 side is amplified within the third gain region 164, and then reflected by the third surface 133 and travels in the first gain region 160 toward the second surface 132. Then, the light is further reflected by the second surface 132, travels through the second gain region 162, and is output from the fourth end surface 184 as the output light 20. Concurrently, the intensity of the light is also amplified within the gain regions 160, 162.

Note that the light generated in the second gain region 162 includes light directly output from the fourth end surface 184 as the output light 20. Similarly, the light generated in the third gain region 164 includes light directly output from the sixth end surface 186 as the output light 22. This light is similarly amplified in the respective gain regions 162, 164.

As described above, the angle β may be the angle larger than 0°. Thereby, it may be possible to prevent direct multiple reflection of the light generated in the gain regions 160, 162, 164 between the fourth end surface 184 and the sixth end surface 186. As a result, it may be possible to prevent formation of a direct resonator in the gain regions 160, 162, 164, and the thus light generated in the gain regions 160, 162, 164 may be output as light with wider spectrum widths and lower coherence, which is SLD light components. Accordingly, speckle noise may be reduced.

The light generated in the fourth gain region 166 is reflected by the reflection surfaces 167 formed at the ends of the longitudinal direction of the fourth gain region 166 and travels back and forth within the fourth gain region 166, and thereby, resonance occurs. That is, a Fabry-Perot resonator is formed by the fourth gain region 166 and the reflection surfaces 167, and light with higher coherence, which is resonant light components, are generated.

As described above, the distance L between the first gain region 160 and the fourth gain region 166 is the distance that produces evanescent coupling. Accordingly, a partial part of the light resonating in the fourth gain region 166 moves to the first gain region 160 due to the evanescent coupling. That is, the light resonating in the fourth gain region 166 senses the first gain region 160 as a high refractive region and the light guided in the first gain region 160, and a part of the light transfers to the light guided in the first gain region 160 in the ways that the both light constructively interfere. The first gain region 160 does not form a resonator, and the phase of the light guided in the first gain region 160 is random and the light resonating in the fourth gain region 166 naturally couples to the light guided in the first gain region 160 at the moment when the phases of the both light match with each other. In this manner, the light traveling back and forth within the fourth gain region 166 moves to the first gain region 160 while resonating in the fourth gain region 166. Then, the light from the fourth gain region 166 that has reached the first gain region 160 are reflected on the surfaces 132, 133 as described above, and output from the end surfaces 184, 186 (light output parts 184, 186) as the output light 20, 22. The fourth gain region 166 has no light output part. Accordingly, nearly all of the light resonating in the fourth gain region 166 except the light lost at the reflection surfaces 167 and the light absorbed by the cladding layers 104, 108 may move to the first gain region 160, and may be output from the light output parts 184, 186.

FIG. 4 is a schematic diagram showing output intensity of the light emitted from the light emitting device 100 with respect to wavelength. The light emitting device 100 may output light including the light with lower coherence (SLD light components) generated in the gain regions 160, 162, 164 and the light with higher coherence (resonant light components) generated in the gain region 166 as output light. The wavelengths of the SLD light component and the resonant light component overlap each other as shown in FIG. 4. In the light emitting device 100, the fourth gain region 166 forms a Fabry-Perot resonator, and the resonator may have multimode. Thus, the resonant light component may contain the light with multiple wavelengths. Accordingly, the light emitting device 100 may reduce the speckle noise even when the output light contains the resonant light component.

Note that, in the light emitting device 100, there are some light moving from the first gain region 160 to the fourth gain region 166 due to evanescent coupling. However, the fourth gain region 166 has no light output part, and the light that have reached the fourth gain region 166 from the first gain region 160 may reach the first gain region 160 again while resonating in the fourth gain region 166 due to evanescent coupling. Then, they may be output from the light output parts 184, 186.

The contact layer 110 is formed on the second cladding layer 108 as shown in FIG. 2. The contact layer 110 may have ohmic contact with the second electrode 114. The upper surface 113 of the contact layer 110 may be a contact surface between the contact layer 110 and the second electrode 114. As the contact layer 110, for example, a p-type GaAs layer may be used.

The contact layer 110 and part of the second cladding layer 108 may compose a columnar part 111. The planar shape of the columnar part 111 is the same as the planar shapes of the gain regions 160, 162, 164, 166 as seen from the stacking direction of the multilayered structure 120. That is, the planar shape of the upper surface 113 of the contact layer 110 may be the same as the planar shapes of the gain regions 160, 162, 164, 166. For example, current channels between the electrodes 112, 114 are determined by the planar shape of the columnar part 111 and, as a result, the planar shapes of the gain regions 160, 162, 164, 166 are determined. Note that, though not illustrated, the side surface of the columnar part 111 may be inclined.

The insulating layer 116 may be formed at sides of the columnar part 111 on the second cladding layer 108. The insulating layer 116 may be in contact with the side surfaces of the columnar part 111. The upper surface of the insulating layer 116 may be continuous with the upper surface 113 of the contact layer 110, for example. As the insulating layer 116, for example, a SiN layer, an SiO₂ layer, an SiON layer, an Al₂O₃ layer, a polyimide layer, or the like may be used.

When the above described material is used for the insulating layer 116, the current between the electrodes 112, 114 may flow in the columnar part 111 sandwiched between the insulating layers 116. The insulating layer 116 may have a smaller refractive index than the refractive index of the second cladding layer 108. In this case, the effective refractive index of the vertical section of the part in which the insulating layer 116 is formed is smaller than the effective refractive index of the vertical section of the part in which the insulating layer 116 is not formed, i.e., the part in which the columnar part 111 is formed. Thereby, in the planar direction, the lights may efficiently be confined within the gain regions 160, 162, 164, 166. Note that, though not illustrated, the above insulating layer 116 may not be provided. In this case, an air surrounding the columnar part 111 may function as the insulating layer 116.

The first electrode 112 is formed on the entire lower surface of the substrate 102. The first electrode 112 may be in contact with a layer that has ohmic contact with the first electrode 112 (the substrate 102 in the illustrated example). The first electrode 112 is electrically connected to the first cladding layer 104 via the substrate 102. The first electrode 112 is one electrode for driving the light emitting device 100. As the first electrode 112, for example, an electrode formed by stacking a Cr layer, an AuGe layer, a Ni layer, and an Au layer in this order from the substrate 102 side may be used.

Note that a second contact layer (not shown) may be provided between the first cladding layer 104 and the substrate 102, the second contact layer may be exposed by dry etching or the like from the opposite side to the substrate 102, and the first electrode 112 may be provided on the second contact layer. Thereby, a single-sided electrode structure may be obtained. This configuration is especially advantageous when the substrate 102 is insulative.

The second electrode 114 is formed in contact with the upper surface 113 of the contact layer 110. Further, the second electrode 114 may be formed on the insulating layer 116 as shown in FIG. 2. The second electrode 114 is electrically connected to the second cladding layer 108 via the contact layer 110. The second electrode 114 is the other electrode for driving the light emitting device 100. As the second electrode 114, for example, an electrode formed by stacking a Cr layer, an AuZn layer, and an Au layer in this order from the contact layer 110 side may be used.

So far, the case of the InGaAlP system has been explained as an example of the light emitting device 100 according to the embodiment, and any material system that can form a gain region may be used for the light emitting device 100. For example, a semiconductor material of an AlGaN system, a GaN system, an InGaN system, a GaAs system, an AlGaAs system, an InGaAs system, an InP system, an InGaAsP system, a GaInNAs system, a ZnCdSe system, or the like may be used.

Further, as the example of the light emitting device 100, the waveguide of the index-guiding type in which the light is confined by the refractive index difference provided between the region where the insulating layer 116 is formed and the region where the insulating layer 116 is not formed, i.e., the region where the columnar part 111 is formed has been explained. On the other hand, in the light emitting device 100, a waveguide of the gain-guiding type in which the columnar part is not formed, i.e., the refractive index difference is not provided and the gain regions serve as waveguide regions as they are may be employed. However, given the coupling efficiency between the gain regions and the guiding loss of coupled light, the waveguide of the index-guiding type is desirable.

The light emitting device 100 according to the embodiment may be applied to a light source of a projector, a display, an illumination device, a measurement device, or the like, for example.

The light emitting device 100 according to the embodiment has the following characteristics, for example.

According to the light emitting device 100, the first gain region 160 is provided from the second surface 132 to the third surface 133 parallel to the first surface 131 on which the light output parts 184, 186 are formed. Accordingly, for example, as compared to the case where the first gain region is not parallel to the first surface, the distance between the light output parts 184, 186 may be made larger without increasing the total length of the gain region. That is, the distance between the light output parts 184, 186 may be made larger while the device length in the direction perpendicular to the light output surface (first surface 131) is made smaller. Thereby, in the light emitting device 100, downsizing of the entire device may be realized, and thus resources are not wasted and the manufacturing cost may be suppressed. More specifically, in the light emitting device 100, the distance D between the light output parts 184, 186 may be set equal to or more than 0.262 mm and less than 3 mm, the angle β may be set equal to or less than 5°, and the entire lengths of the gain regions 160, 162, 164 may be set equal to or more than 1.5 mm and equal to or less than 3 mm.

Further, according to the light emitting device 100, the fourth gain region 166 is formed separately from at least one of the gain regions 160, 162, 164 at the distance that produces evanescent coupling. Accordingly, the light generated in the fourth gain region 166 may be output from the end surface 184 of the gain region 162 or the end surface 186 of the gain region 164, and the intensity of light emitted from the light emitting device may increase. Furthermore, the fourth gain region 166 may form a resonator. Accordingly, the light emitting device 100 may output the light including the SLD light component and the resonant light component as output light. Therefore, speckle noise may be reduced compared to a semiconductor laser while output power increases compared to an ordinary SLD. Especially, in the light emitting device 100, the fourth gain region 166 forms a Fabry-Perot resonator and the resonator may have multimode. Thus, the resonant light component may contain the light with multiple wavelengths. Accordingly, the light emitting device 100 may reduce speckle noise enough even when the output light contains the resonant light component.

In addition, as shown in FIG. 2, the fourth gain region 166 may be formed to be surrounded by the first gain region 160, the second gain region 162, the third gain region 164, and the first surface 131 in the plan view from the stacking direction of the multilayered structure 120. Thereby, the entire area of the light emitting device 100 may not increase, even when the fourth gain region 166 is formed. As a result, resources (substrates, gasses, chemicals, etc. necessary for manufacturing of the light emitting device) are not wasted and the manufacturing cost may be suppressed.

According to the light emitting device 100, the first gain region 160 and the second gain region 162 are connected to the second surfaced 132 and may be tilted at the first angle α1 with respect to the perpendicular line P2 of the second surface 132, and the first gain region 160 and the third gain region 164 are connected to the third surface 133 and may be tilted at the second angle α2 with respect to the perpendicular line P3 of the third surface 133. The angles α1, α2 may be equal to or more than the critical angle. Accordingly, the surfaces 132, 133 may totally reflect the light generated in the gain regions 160, 162, 164, 166. Therefore, in the light emitting device 100, light loss on the surfaces 132, 133 (the end surfaces 181, 183 and the end surfaces 182, 185) may be suppressed and the light may be efficiently reflected. Further, the process of forming the reflection films on the surfaces 132, 133 is not necessary, and the manufacturing cost and the materials and resources used for the manufacturing the films may be reduced.

According to the light emitting device 100, the length of the first gain region 160 may be made larger than the length of the second gain region 162 and the length of the third gain region 164. Thereby, the distance D between the light output parts 184, 186 may reliably be made larger.

According to the light emitting device 100, the longitudinal direction of the first gain region 160 and the longitudinal direction of the fourth gain region 166 may be made in parallel, and the distance L between the first gain region 160 and the fourth gain region 166 may be set to the distance that produces evanescent coupling. Thereby, evanescent coupling may efficiently be produced between the first gain region 160 and the fourth gain region 166.

According to the light emitting device 100, the distance L between the first gain region 160 and the fourth gain region 166 may be from 100 nm to 40 μm. Thereby, evanescent coupling may efficiently be produced between the first gain region 160 and the fourth gain region 166. For example, when the distance L is smaller than 100 nm, the light traveling within the first gain region 160 may also resonate. If the distance L is larger than 40 μm, sufficient evanescent coupling may not be produced.

### 2. Manufacturing Method of Light Emitting Device

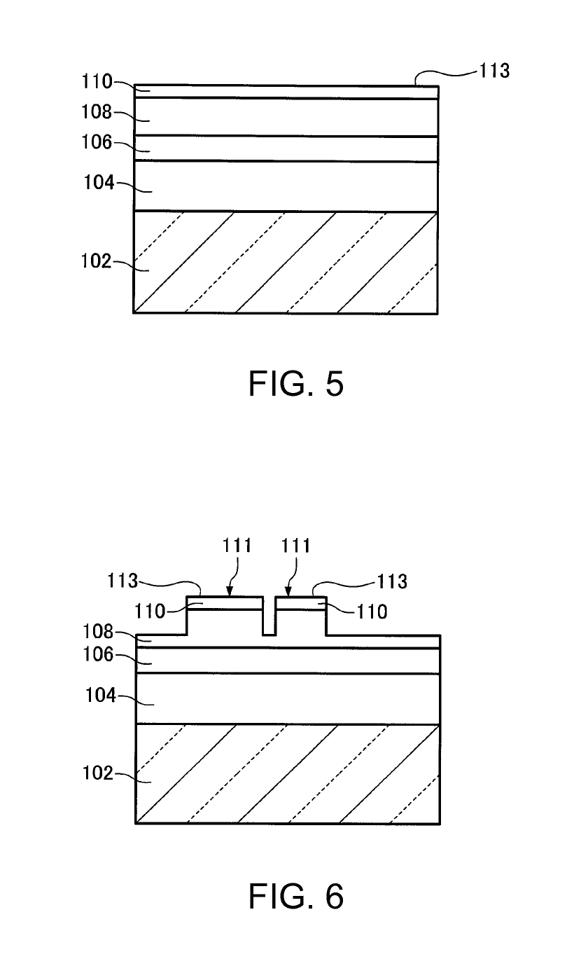

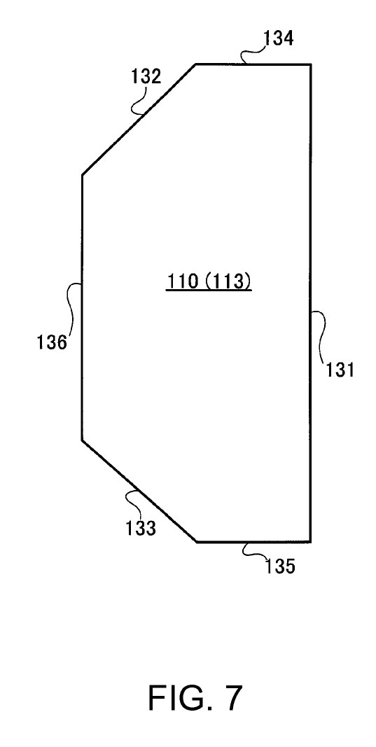

Next, a manufacturing method of the light emitting device according to the embodiment will be explained with reference to the drawings. FIG. 5 is a sectional view schematically showing a manufacturing process of the light emitting device 100 according to the embodiment corresponding to FIG. 2. FIG. 6 is a plan view schematically showing a manufacturing process of the light emitting device 100 according to the embodiment corresponding to FIG. 1. FIG. 7 is a sectional view schematically showing a manufacturing process of the light emitting device 100 according to the embodiment corresponding to FIG. 2.

As shown in FIG. 5, on the substrate 102, the first cladding layer 104, the active layer 106, the second cladding layer 108, and the contact layer 110 are epitaxially grown in this order. As the growth method, for example, an MOCVD (Metal Organic Chemical Vapor Deposition) method, an MBE (Molecular Beam Epitaxy) method, or the like may be used.

As shown in FIG. 6, the contact layer 110 and the second cladding layer 108 are patterned. Through the process, the columnar part 111 may be formed.

As shown in FIGS. 3 and 7, the contact layer 110, the second cladding layer 108, the active layer 106, the first cladding layer 104, and the substrate 102 are patterned, and the reflection surfaces 167, the second surface 132, and the third surface 133 are formed. The patterning is performed using photolithography and etching, for example.

Note that, though not illustrated, as long as the second and the third surfaces 132, 133 of the active layer 106 are exposed and the opening parts produced when the reflection surfaces 167 are formed penetrate the active layer 106, parts of the first cladding layer 104 and the substrate 102 are not necessarily patterned. Further, at the manufacturing process, the surfaces 132, 133 have been formed at the same time with the reflection surfaces 167, but they may be formed separately. When the surfaces 132, 133 are formed at the same time with the reflection surfaces 167, use of resources such as etching gases may be reduced.

The surfaces 134, 135, 136 may be formed at the same time with the surfaces 132, 133 using photolithography and etching, but they may also be formed by cleavage or the like after fabrication of the columnar part 111 and the electrodes 112, 114, which will be described later.

As shown in FIG. 2, the insulating layer 116 is formed to cover the side surfaces of the columnar part 111. Specifically, first, an insulating member (not shown) is deposited on the second cladding layer 108 (including the contact layer 110 and opening parts produced when the reflection surfaces 167 or the surface 132, 133 are formed) by a CVD (Chemical Vapor Deposition) method, a coating method, or the like, for example. Then, the upper surface 113 of the contact layer 110 is exposed using etching or the like, for example. Through the above described processes, the insulating layer 116 may be formed.

Then, the second electrode 114 is formed on the contact layer 110 and on the insulating layer 116. Then, the first electrode 112 is formed on the lower surface of the substrate 102. The first electrode 112 and the second electrode 114 are formed by vacuum evaporation, for example. Note that the order of formation of the first electrode 112 and the second electrode 114 is not particularly limited. Further, to expose the reflection surfaces 167 at the next process, it is desirable that the second electrode 114 is not formed on the insulating layer 116 at the opening parts produced when the reflection surfaces 167 or the surfaces 132, 133 are formed using a lift-off method or the like.

Then, the reflection surfaces 167 (and the surfaces 132, 133, if they have already been formed) are exposed by etching the insulating layer 116. If the surfaces 132, 133 have not formed yet, then they may be formed by cleavage or the like.

Through the above described processes, the light emitting device 100 according to the embodiment may be manufactured.

According to the manufacturing method of the light emitting device 100, the light emitting device 100 in which the distances of the light output parts may be made larger may be obtained.

### 3. Modified Examples of Light Emitting Device

Next, light emitting devices according to modified examples of the embodiment will be explained with reference to the drawings. Below, in the light emitting devices according to modified examples of the embodiment, the same signs are assigned to the members having the same functions as those of the light emitting device 100 according to the embodiment, and a detailed explanation will be omitted.

### 3.1. Light Emitting Device According to the First Modified Example

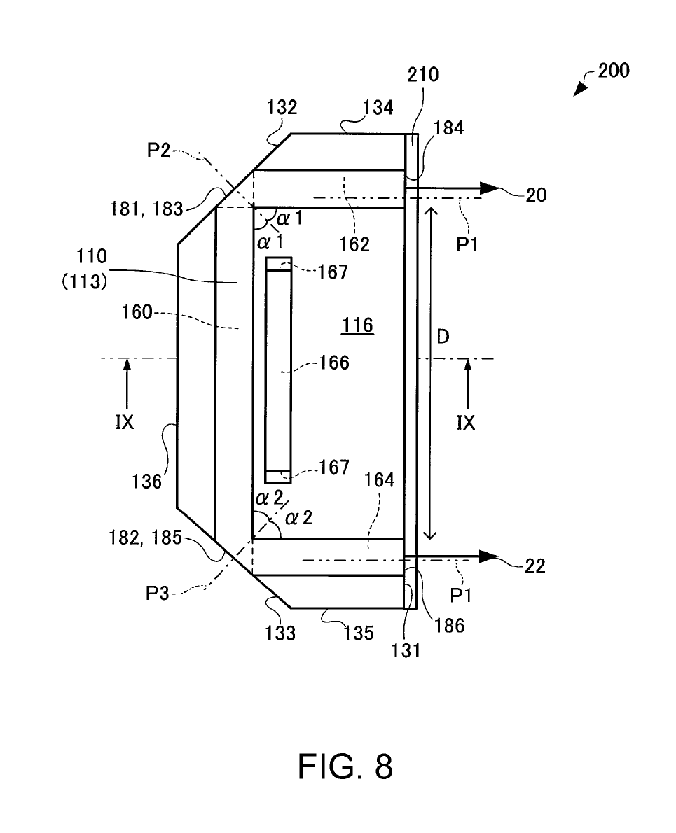

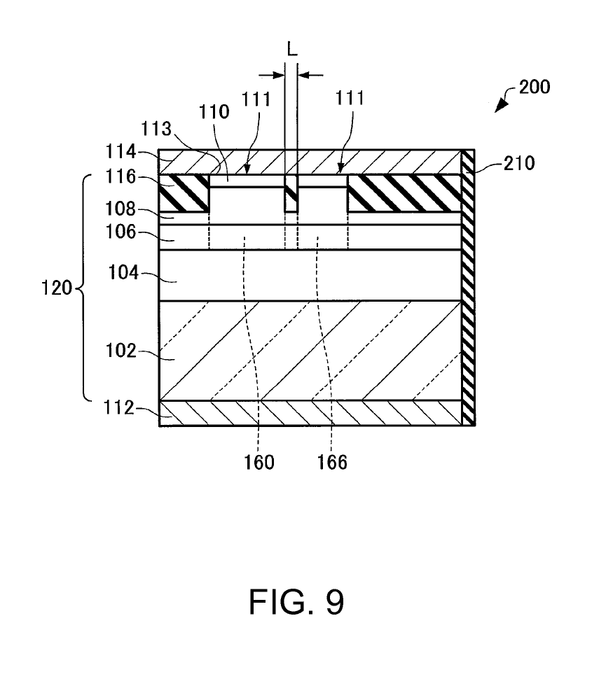

First, a light emitting device according to the first modified example of the embodiment will be explained with reference to the drawings. FIG. 8 is a plan view schematically showing a light emitting device 200 according to the first modified example of the embodiment. FIG. 9 is a sectional view along IX-IX line of FIG. 8 schematically showing the light emitting device 200 according to the first modified example of the embodiment. Note that, in FIG. 8, for convenience, illustration of the second electrode 114 is omitted.

In the example of the light emitting device 100, as shown in FIG. 1, the second gain region 162 and the third gain region 164 have been connected to the first surface 131 and tilted at the angle β with respect to the perpendicular line P1 of the first surface 131 in the plan view from the stacking direction of the multilayered structure 120 as shown in FIG. 1. The angle β has been the angle larger than 0°.

On the other hand, in the example of the light emitting device 200, as shown in FIG. 8, the second gain region 162 and the third gain region 164 are orthogonal to the first surface 131 in the plan view from the stacking direction of the multilayered structure 120. More specifically, the longitudinal direction of the second gain region 162 and the longitudinal direction of the third gain region 164 are orthogonal to the first surface 131. That is, the longitudinal direction of the second gain region 162 and the longitudinal direction of the third gain region 164 are in parallel to the perpendicular line P1 of the first surface 131.

The light emitting device 200 has an antireflection film 210 as shown in FIGS. 8 and 9. The antireflection film 210 is formed on the first surface 131 and covers the end surfaces 184, 186 serving as light output parts. For the antireflection film 210, an SiO₂ layer, a Ta₂O₅ layer, an Al₂O₃ layer, a TiN layer, a TiO₂ layer, an SiON layer, an SiN layer, a multilayer film of them, or the like may be used. The antireflection film 210 is formed using a CVD method or ion-assisted deposition method, for example. The antireflection film 210 may reduce reflectance of the first surface 131 (reflectance of the end surfaces 184, 186) in the wavelength band of the light generated in the active layer 106.

According to the light emitting device 200, even when the longitudinal direction of the second gain region 162 and the longitudinal direction of the third gain region 164 are in parallel to the perpendicular line P1 of the first surface 131, it may be possible to prevent direct multiple reflections of the light between the fourth end surface 184 and the sixth end surface 186 by the antireflection film 210. As a result, the light emitting device 200 may output light containing the SLD light component and reduce speckle noise.

### 3.2. Light Emitting Device According to the Second Modified Example

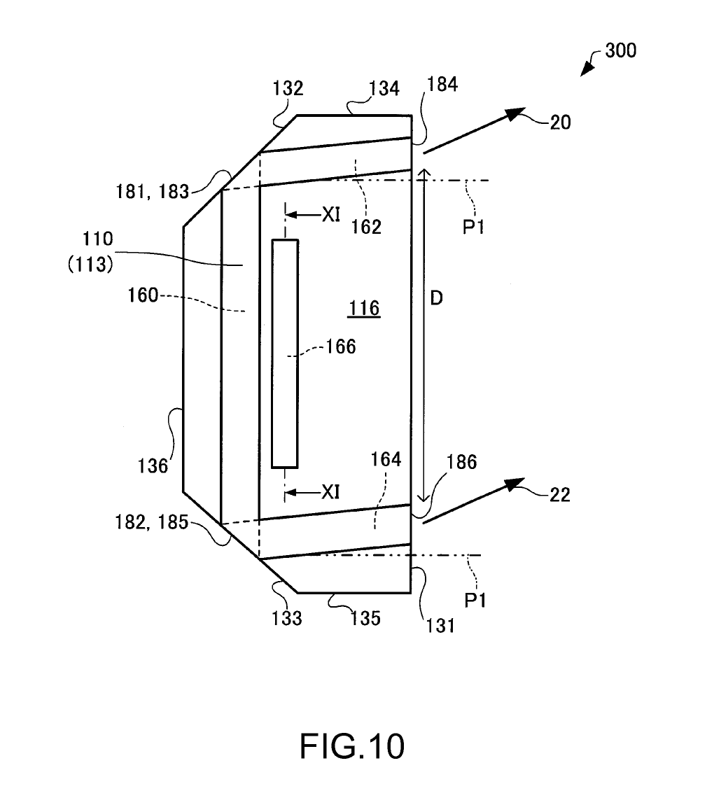

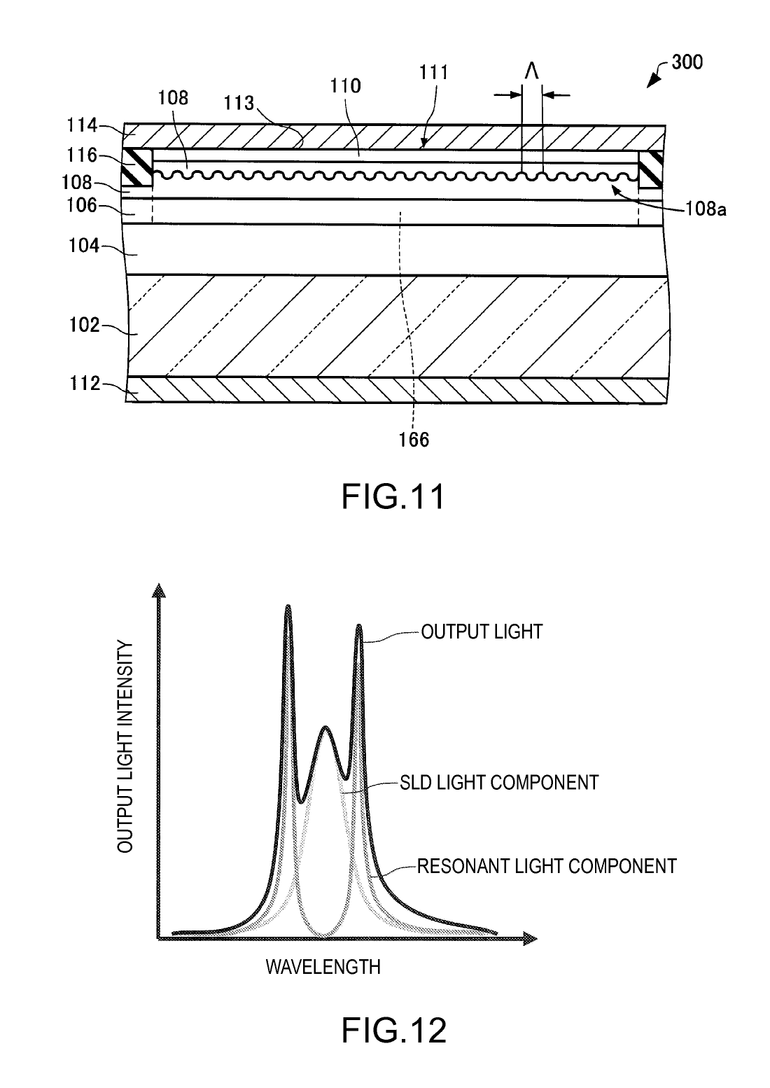

Next, a light emitting device according to the second modified example of the embodiment will be explained with reference to the drawings. FIG. 10 is a plan view schematically showing a light emitting device 300 according to the second modified example of the embodiment. FIG. 11 is a sectional view along XI-XI line of FIG. 10 schematically showing the light emitting device 300 according to the second modified example of the embodiment. Note that, in FIG. 10, for convenience, illustration of the second electrode 114 is omitted.

In the example of the light emitting device 100, as shown in FIGS. 1 and 3, the fourth gain region 166 has formed the Fabry-Perot resonator.

On the other hand, in the light emitting device 300 as shown in FIGS. 10 and 11, the fourth gain region 166 may form a distributed feedback (DFB) resonator. That is, as shown in FIG. 11, a periodic structure 108a composing the DFB resonator is formed in the second cladding layer 108 corresponding to the fourth gain region 166. The resonant wavelength of the DFB resonator is determined by the pitch Λ of the periodic structure 108a. The periodic structure 108a may be formed by growing the second cladding layer 108 halfway in the first growth, then, a convexo-concave surface is formed by interference exposure and etching, and growing the second cladding layer 108 having a different refractive index again on the convexo-concave surface in the second growth (the refractive index of the second cladding layer 108 formed in the second growth is different from that formed in the first growth). More specifically, the second cladding layer 108 having the different refractive index is formed by growing an InGaAlP layer having a different composition, for example. Note that, though not illustrated, it is only necessary that a structure in which the effective refractive index periodically changes is formed, and the convexo-concave surface may be formed entire or in parts of the first cladding layer 104 or the active layer 106 or may be formed across the interfaces between the respective layers such as part of the second cladding layer 108 and part of the active layer 106, or the like.

FIG. 12 is a schematic diagram showing the intensity of the light emitted from the light emitting device 300 with respect to wavelength. In the light emitting device 300, the fourth gain region 166 forms the DFB resonator, and, if the effective refractive index difference due to convexes and concaves is smaller, for example, the resonant light component may be the single mode or the double mode (the double mode in the illustrated example) as shown in FIG. 12. However, the light are confined by multiple reflections by the periodic structure 108a, and thus, the light hardly leak outside of the fourth gain region 166. Therefore, the light emitting device 300 has a slightly larger influence on the speckle, but a better light confinement compared to the light emitting device 100, and light loss may be suppressed.

Note that, in the embodiment of the invention, unlike a typical DFB laser, it is not necessary to reduce the number of modes by making the resonant light component resonate in the entire fourth gain region 166 as a single resonator. That is, the effective refractive index difference between the convex parts and the concave parts may be made larger by a method of enlarging the depth of the concaves, forming convexes and concaves on the active layer 106, or the like, and thus, plural DFB-like resonant modes may be formed within the fourth gain region 166 and their wavelengths may be different. Thereby, the influence on spackle may be reduced and leakage of light from the fourth gain region 166 may be suppressed.

### 3.3. Light Emitting Device According to the Third Modified Example

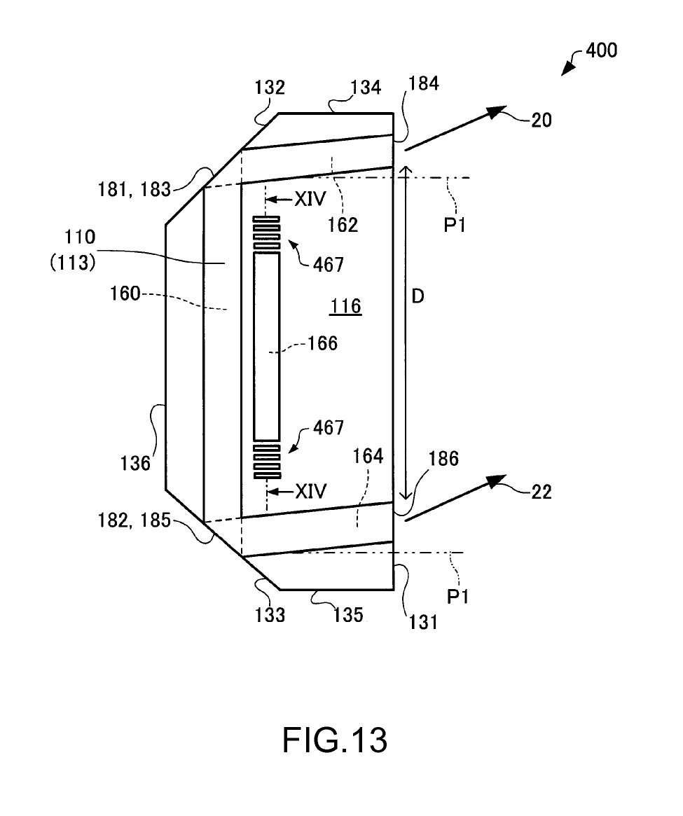

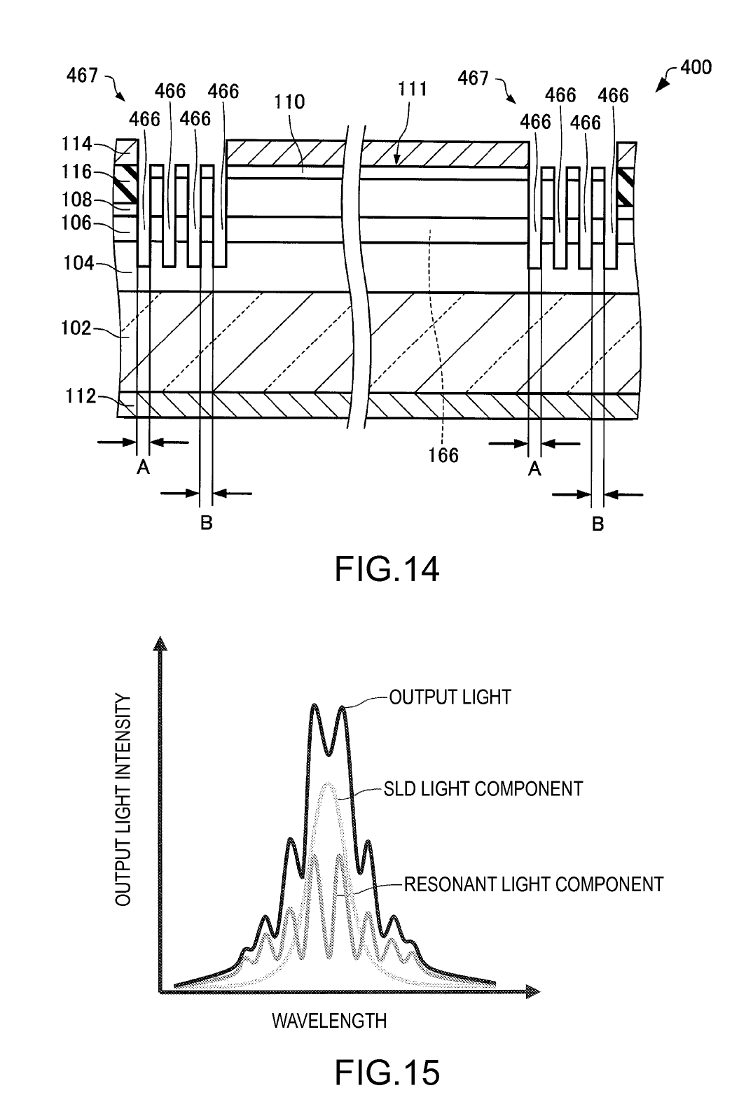

Next, a light emitting device according to the third modified example of the embodiment will be explained with reference to the drawings. FIG. 13 is a plan view schematically showing a light emitting device 400 according to the third modified example of the embodiment. FIG. 14 is a sectional view along XIV-XIV of FIG. 13 schematically showing the light emitting device 400 according to the third modified example of the embodiment. Note that, in FIG. 13, for convenience, an illustration of the second electrode 114 is omitted.

In the example of the light emitting device 100, as shown in FIGS. 1 and 3, the fourth gain region 166 has formed the Fabry-Perot resonator.

On the other hand, in the light emitting device 400, as shown in FIGS. 13 and 14, the fourth gain region 166 may form a distributed Bragg reflector (DBR) resonator. That is, distributed Bragg reflector mirrors (also referred to as “DBR”) 467 are formed at the ends of the longitudinal direction of the fourth gain region 166. In the example shown in FIGS. 13 and 14, the DBR 467 includes plural groove parts 466 periodically arranged at predetermined intervals. The planar shape of the groove part 466 is a rectangular shape, for example. It is desirable that the groove part 466 is provided so as to penetrate the active layer 106. In the example shown in FIG. 14, the bottom surface of the groove part 466 is located between the upper surface and the lower surface of the first cladding layer 104. The groove part 466 may be hollow or embedded with an insulating material. The number of the groove parts 466 is not particularly limited, and the DBR 467 with higher reflectance may be obtained by increasing the number. In the example shown in FIG. 14, the groove parts 466 have widths A and arranged at intervals B. The resonant wavelength may be determined by the width A and the interval B. The DBR 467 may be formed by interference exposure and etching.

FIG. 15 is a schematic diagram showing the intensity of the light emitted from the light emitting device 400 with respect to wavelength. In the light emitting device 400, the fourth gain region 166 forms the DBR resonator. The size of the fourth gain region 166 in the longitudinal direction may be sufficiently larger compared to the wavelength of the light emitted from the gain region (in the case of visible light, several hundreds of nanometers), and the resonator may have the multimode. Thus, the resonant light component may contain the light with multiple wavelengths. Therefore, the influence on speckle is smaller and speckle noise may be reduced. Further, the light confinement effect may be better, and light loss may be suppressed.

### 3.4. Light Emitting Device According to the Fourth Modified Example

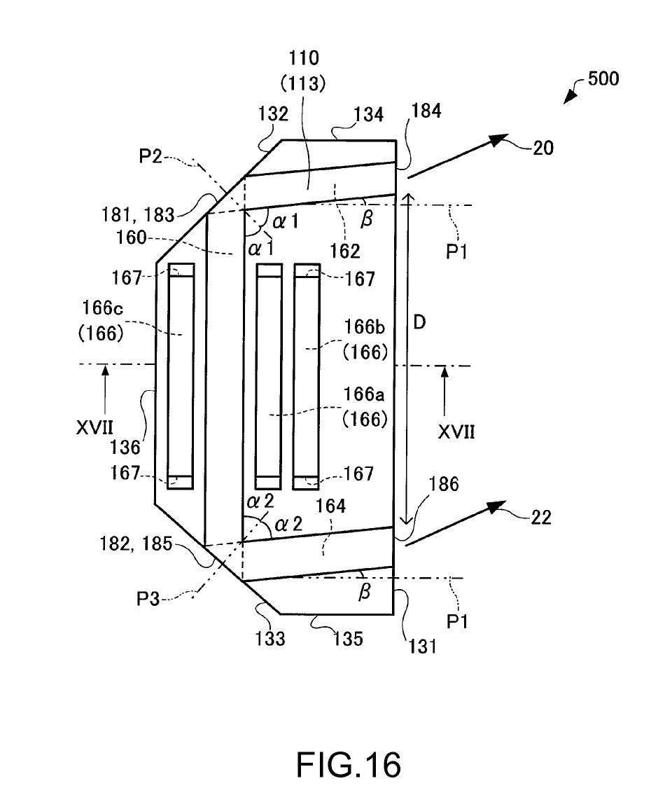

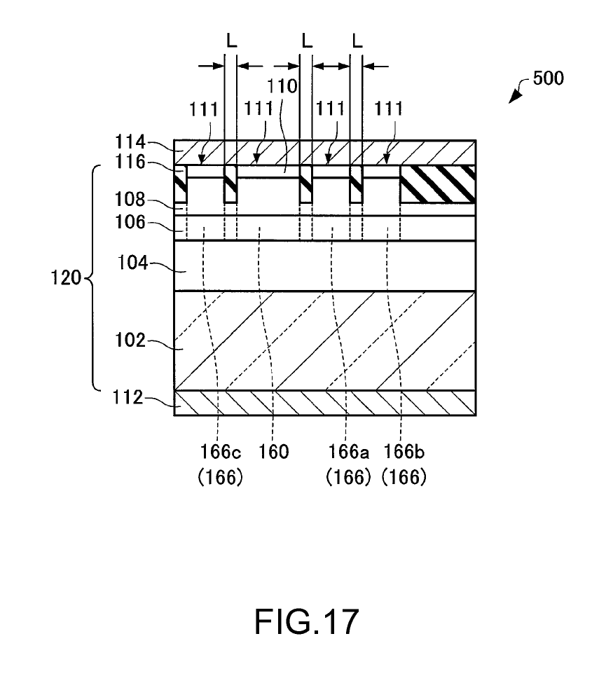

Next, a light emitting device according to the fourth modified example of the embodiment will be explained with reference to the drawings. FIG. 16 is a plan view schematically showing a light emitting device 500 according to the fourth modified example of the embodiment. FIG. 17 is a sectional view along XVII-XVII of FIG. 16 schematically showing the light emitting device 500 according to the fourth modified example of the embodiment. Note that, in FIG. 16, for convenience, an illustration of the second electrode 114 is omitted.

In the example of the light emitting device 100, as shown in FIGS. 1 and 2, one fourth gain region 166 forming the resonator has been provided.

On the other hand, in the light emitting device 500, as shown in FIGS. 16 and 17, a plurality of the fourth gain regions 166 forming resonators are provided. In the illustrated example, three fourth gain regions 166 are provided, however, the number is not particularly limited. The respective plural fourth gain regions 166 are provided in parallel to the first gain region 160 in the plan view from the stacking direction of the multilayered structure 120 as shown in FIG. 16. In the illustrated example, a fourth gain region 166a is provided at the first surface 131 side of the first gain region 160 with the distance L kept from the first gain region 160. Further, a fourth gain region 166b is provided at the first surface 131 side of the fourth gain region 166a with the distance L kept from the fourth gain region 166a. Furthermore, a fourth gain region 166c is provided at the sixth surface 136 side of the first gain region 160 with the distance L kept from the first gain region 160.

The distance L is the distance that produces evanescent coupling as described above. Therefore, parts of the light resonating within the fourth gain region 166a may reach not only the first gain region 160 but also the fourth gain region 166b. Part of the light resonating within the fourth gain region 166b may reach the fourth gain region 166a. Parts of the light resonating within the fourth gain region 166c may reach the first gain region 160. In this manner, the light may move among the gain regions 160, 166a, 166b, 166c because of the evanescent coupling. The gain regions 166a, 166b, 166c have no light output part. Accordingly, nearly all of the light resonating within the gain regions 166a, 166b, 166c except the light lost in the reflection surfaces 167 and the light absorbed by the cladding layers 104, 108 may finally move to the first gain region 160, and may be output from the light output parts 184, 186.

According to the light emitting device 500, the number of fourth gain regions 166 is larger than that of the light emitting device 100, and light emission the intensity of light emitted from the device may increased by the number.

### 3.5. Light Emitting Device According to the Fifth Modified Example

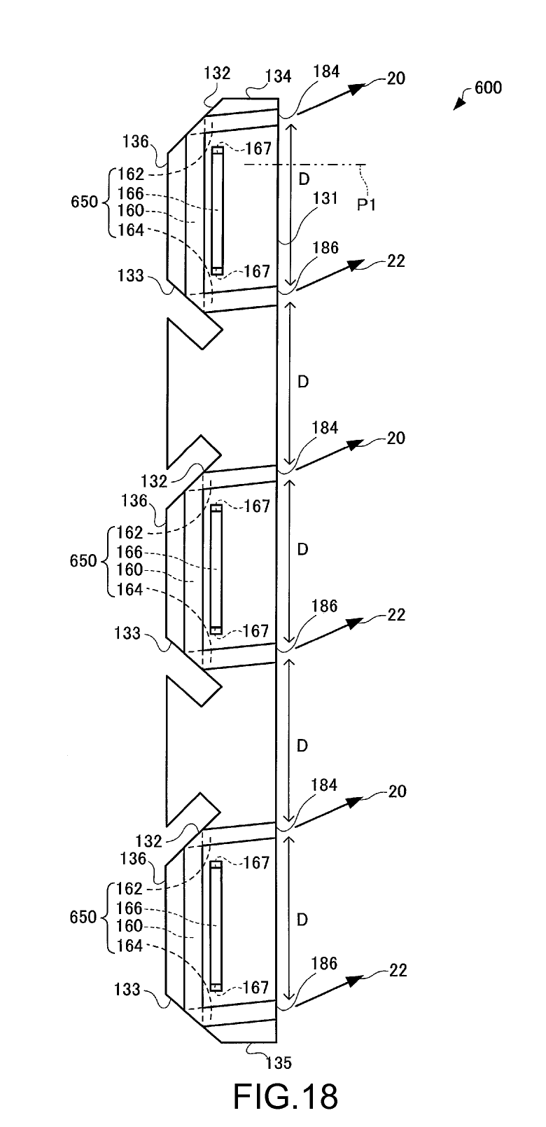

Next, a light emitting device according to the fifth modified example of the embodiment will be explained with reference to the drawings. FIG. 18 is a plan view schematically showing a light emitting device 600 according to the fifth modified example of the embodiment. Note that, in FIG. 18, for convenience, an illustration of the second electrode 114 is omitted.

In the example of the light emitting device 100, as shown in FIG. 1, one first gain region 160, one second gain region 162, one third gain region 164, and one fourth gain region 166 have been provided.

On the other hand, in the light emitting device 600, as shown in FIG. 18, plural first gain regions 160, plural second gain regions 162, plural third gain regions 164, and plural fourth gain regions 166 are respectively provided. That is, the gain regions 160, 162, 164, 166 may form a group of gain regions 650, and, in the light emitting device 600, plural groups of gain regions 650 are provided. In the illustrated example, three groups of gain regions 650 are provided, however, the number of the groups is not particularly limited.

The plural groups of gain regions 650 are arranged in a direction orthogonal to the direction in which the perpendicular line P1 of the first surface 131 extends. More specifically, they are arranged so that, in the adjacent groups of gain regions 650, the distance between the sixth end surface 186 of one group of gain regions 650 and the fourth end surface 184 of the other group of gain regions 650 may be D (the distance between the light output parts). Thereby, the light 20, 22 may easily be allowed to enter a lens array, which will be described later.

According to the light emitting device 600, higher power may be realized compared to the example of the light emitting device 100.

### 4. Projector

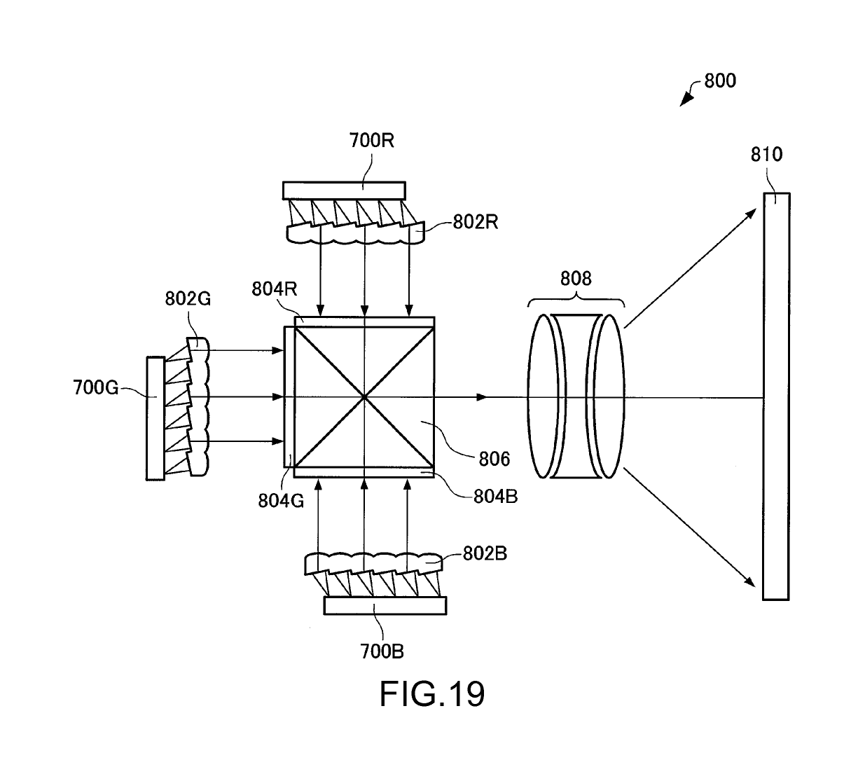

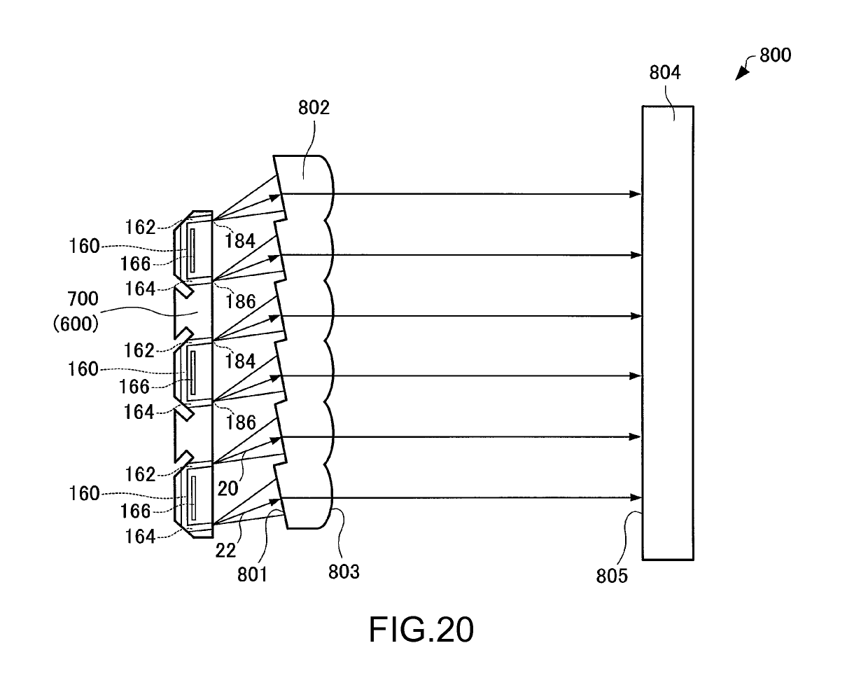

Next, a projector according to the embodiment will be explained with reference to the drawings. FIG. 19 schematically shows a projector 800 according to the embodiment. FIG. 20 schematically shows part of the projector 800 according to the embodiment. Note that, in FIG. 19, for convenience, a casing forming the projector 800 is omitted, and further, a light source 700 is simplified for illustration. Further, in FIG. 20, for convenience, the light source 700, a lens array 802, and a liquid crystal light valve 804 are illustrated, and further, the light source 700 is simplified for illustration.

The projector 800 includes a red light source 700R, a green light source 700G, and a blue light source 700B that output red light, green light, and blue light as shown in FIG. 19. The light sources 700R, 700G, 700B have the light emitting devices according to the invention. In the following example, the light sources 700R, 700G, 700B having the light emitting devices 600 as the light emitting devices according to the invention will be explained.

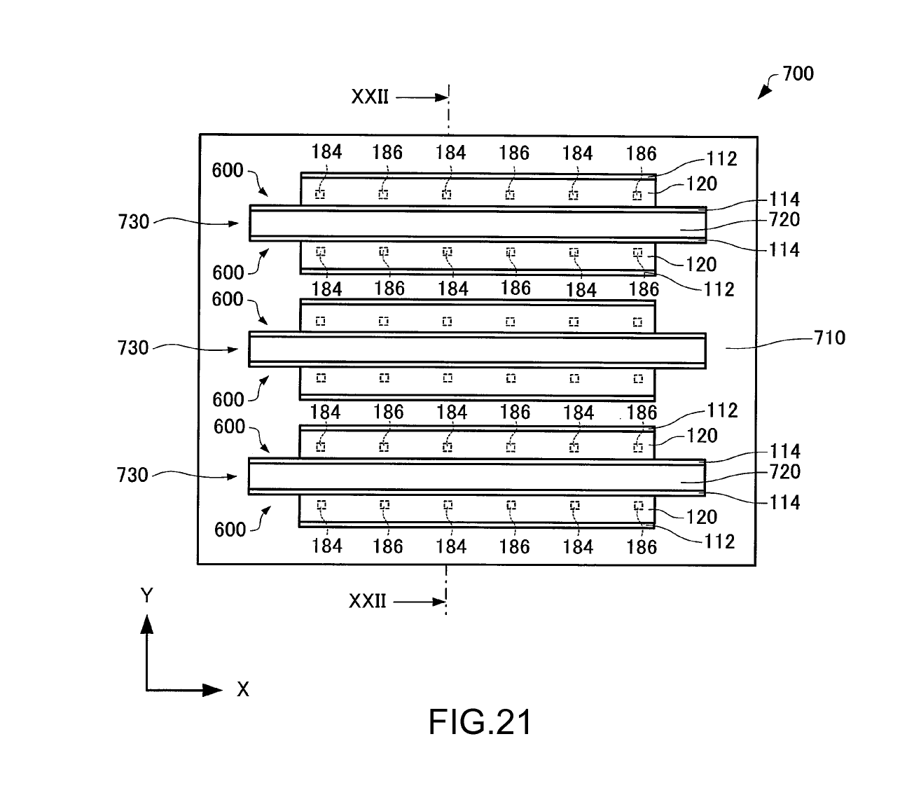

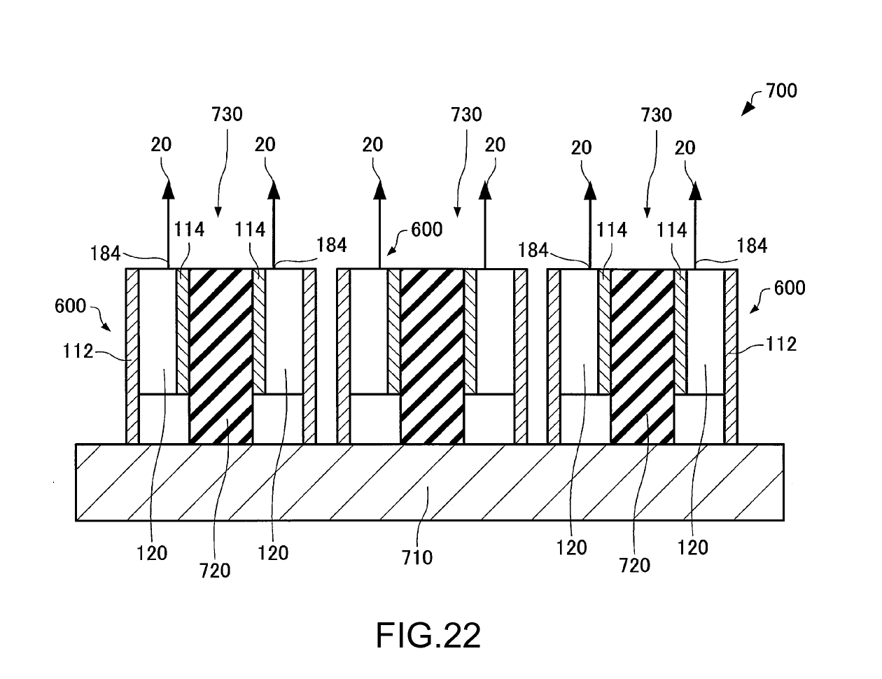

FIG. 21 schematically shows the light source 700 of the projector 800 according to the embodiment. FIG. 22 is a sectional view along XXII-XXII line of FIG. 2 schematically showing the light source 700 of the projector 800 according to the embodiment.

The light source 700 may have the light emitting devices 600, a base 710, and sub-mounts 720 as shown in FIGS. 21 and 22.

The two light emitting devices 600 and the sub-mount 720 may form a structure 730. Plural structures 730 are provided and arranged in the direction (Y-axis direction) orthogonal to the arrangement direction (X-axis direction) of the end surfaces 184, 186 which are the light output parts of the light emitting devices 600 as shown in FIG. 21. The structures 730 may be arranged so that the distance between the light output parts in the X-axis direction and the distance between the light output parts in the Y-axis direction may be equal. Thereby, the light output from the light emitting devices 600 may easily enter the lens array 802.

The two light emitting devices 600 forming the structure 730 are provided with the sub-mount 720 sandwiched in between. In the example shown in FIGS. 21 and 22, the two light emitting devices 600 are provided so that the second electrodes 114 may be opposed via the sub-mount 720. On part of the surface of the sub-mount 720 being contact with the second electrode 114, for example, wiring is formed. Thereby, voltages may individually be supplied to the respective plural second electrodes 114. As the material of the sub-mount 720, for example, aluminum nitride and aluminum oxide may be cited.

The base 710 supports the structures 730. In the example shown in FIG. 22, the base 710 is connected to the first electrodes 112 of the plural light emitting devices 600. Thereby, the base 710 may function as a common electrode of the plural first electrodes 112. As the material of the base 710, for example, copper and aluminum may be cited. Although not illustrated, the base 710 may be connected to a heat sink via a Peltier device.

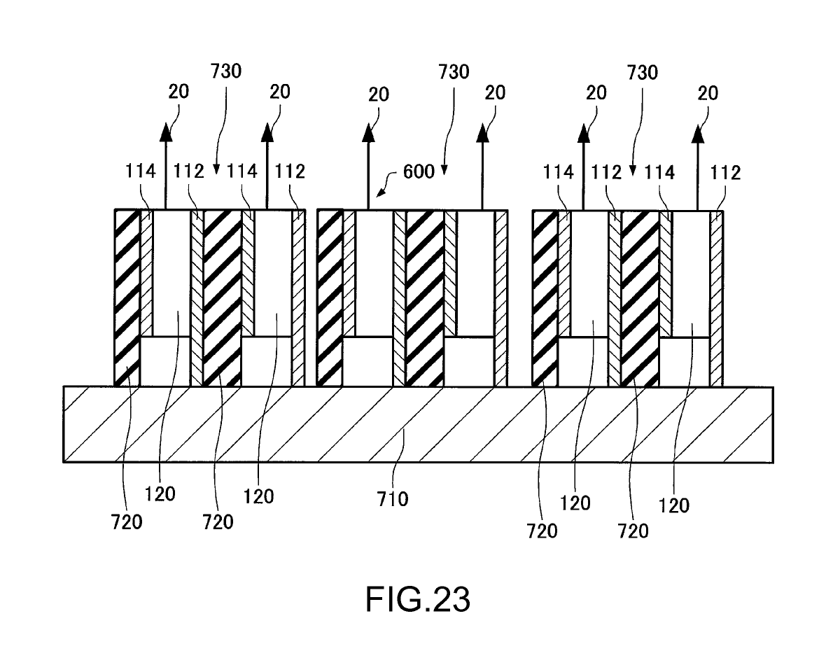

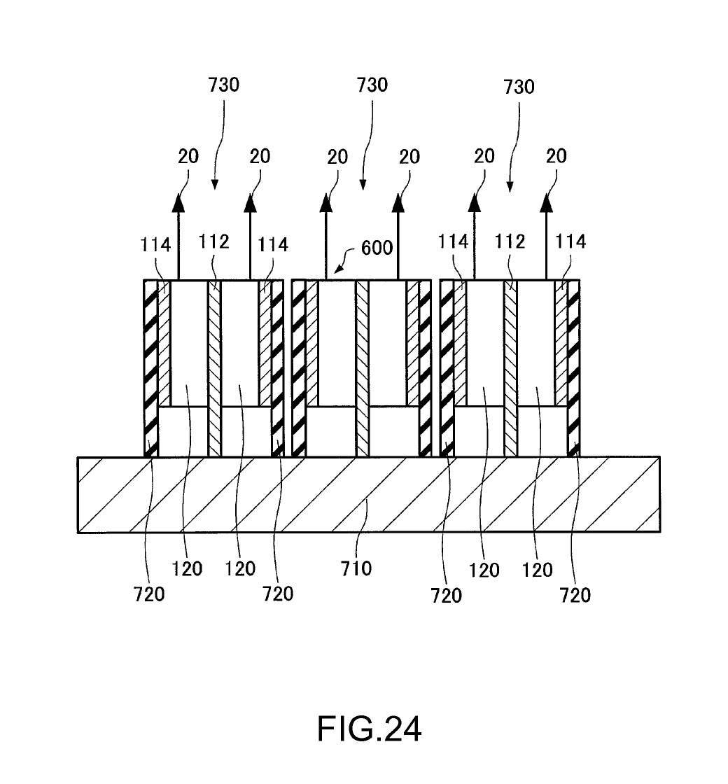

Note that the form of the structure 730 is not limited to the example shown in FIGS. 21 and 22. For example, as shown in FIG. 23, the two light emitting devices 600 forming the structure 730 may be provided so that the first electrode 112 of one light emitting device 600 and the second electrode 114 of the other light emitting device 600 may be opposed via the sub-mount 720. Alternatively, as shown in FIG. 24, they may be provided so that the first electrodes 112 of the two light emitting devices 600 may be a common electrode.

As shown in FIG. 19, the projector 800 further includes lens arrays 802R, 802G, 802B and transmissive liquid crystal light valves (light modulation devices) 804R, 804G, 804B, and a projection lens (projection device) 808.

The light output from the respective light sources 700R, 700G, 700B enter the respective lens arrays 802R, 802G, 802B. As shown in FIG. 20, the lens array 802 may have flat surfaces 801 that the light 20, 22 output from the light output parts 184, 186 enter at the light source 700 side. The plural flat surfaces 801 are provided in correspondence with the plural light output parts 184, 186 and arranged at equal distances. Further, the normal lines of the flat surfaces 801 are tilted with respect to the optical axes of the light 20, 22. By the flat surfaces 801, the optical axes of the light 20, 22 may be made orthogonal to an irradiated surface 805 of the liquid crystal light valve 804. Especially, when the angles β formed by the first surface 131 and the second and the third gain region 162, 164 are not 0°, the light 20, 22 output from the respective light output parts 184, 186 are tilted with respect to the perpendicular line P1 of the first surface 131, and thus, it is desirable that the flat surfaces 801 are provided.

The lens array 802 may have convex curved surfaces 803 at the liquid crystal light valve 804 side. Plural convex curved surfaces 803 are provided in correspondence with the plural flat surfaces 801 and arranged at equal distances. The light 20, 22 with optical axes converted on the flat surfaces 801 are collected (collimated) or traveling at diffusion angles reduced by the convex curved surfaces 803, and may be superimposed (partially superimposed). Thereby, the liquid crystal light valve 804 may be irradiated with good uniformity.

As described above, the lens array 802 may control the optical axes of the light 20, 22 output from the light source 700 and integrated the light 20, 22.

As shown in FIG. 19, the light integrated by the respective lens arrays 802R, 802G, 802B enter the respective liquid crystal light valves 804R, 804G, 804B. The respective liquid crystal light valves 804R, 804G, 804B respectively modulate the incident light in response to image information. Then, the projection lens 808 enlarges images formed by the liquid crystal light valves 804R, 804G, 804B and projects them on a screen (display surface) 810.

Further, the projector 800 may include a cross dichroic prism (color combining unit) 806 that combines light output from the liquid crystal light valves 804R, 804G, 804B and guides the light to the projection lens 808.

The three colors of light modulated by the respective liquid crystal light valves 804R, 804G, 804B enter the cross dichroic prism 806. The prism is formed by bonding four right angle prisms, and a dielectric multilayer film that reflects red light and a dielectric multilayer film that reflects blue light are provided crosswise on its inner surfaces. By the dielectric multilayer films, the three colors of light are combined and light representing a color image is formed. Then, the combined light is projected on the screen 810 by the projection lens 808 as a projection system, and the enlarged image is displayed thereon.

According to the projector 800, the light emitting devices 600 that may make distances between the plural light output parts larger is provided. Accordingly, in the projector 800, alignment of the lens array 802 may be easy and the liquid crystal light valve 804 may be irradiated with good uniformity.

Note that, in the above described example, transmissive liquid crystal light valves have been used as the light modulation devices, however, other light valves than liquid crystal, or reflective light valves may be used. As the light valves, for example, reflective liquid crystal light valves and digital micromirror devices may be used. Further, the configuration of the projection system may appropriately be changed depending on the type of the light valves employed.

Further, the light source 700 and the lens array 802 may be modularized in alignment with each other. Furthermore, the light source 700, the lens array 802, and the light valve 804 may be modularized in alignment with one another.

In addition, the light source 700 may also be applied to a light source device of a scanning type image display device (projector) having a means of scanning light for displaying an image in a desired size on a display surface.

The above described embodiments and modified examples are just examples, and the invention is not limited to these. For example, the respective embodiments and the respective modified examples may be appropriately combined.

The embodiments of the invention have been specifically explained above, and a person skilled in the art could easily understand that many modifications may be carried out without substantively departing from the new spirit and effect of the invention. Therefore, these modified examples are included in the range of the invention.

The entire disclosure of Japanese Patent Application No. 2011-059046, filed Mar. 17, 2011 is expressly incorporated by reference herein.

What is claimed is:

1. A light emitting device comprising:
a first layer that generates light by injection current, and forms a waveguide for the light;
a second layer and a third layer that sandwich the first layer and suppress leakage of the light; and
an electrode that injects the current into the first layer,
wherein the waveguide has a first region having a belt-like linear shape, a belt-like second region, a belt-like third region, and a belt-like fourth region,
the first region and the second region are connected at a first reflection part provided on a first side surface of the first layer,
the first region and the third region are connected at a second reflection part provided on a second side surface of the first layer different from the first side surface,
the second region and the third region are connected to a third side surface of the first layer which is an output surface that is different from the first and second side surface,
a longitudinal direction of the first region is parallel to the output surface,
the second region and the third region are tilted at the same angle and connected to the third side surface as seen from a stacking direction of the first layer, and the second layer,
a distance between the fourth region and at least one of the first region, the second region, and the third region is a distance that produces evanescent coupling, and
the fourth region forms a resonator.

2. A light emitting device comprising:
a first layer that generates light by injection current and forms a waveguide for the light;
a second layer and a third layer that sandwich the first layer and suppress leakage of the light; and
an electrode that injects the current into the first layer,
wherein the waveguide has a first region having a belt-like linear shape, a belt-like second region, a belt-like third region, and a belt-like fourth region,
the first region and the second region are connected at a first reflection part provided on a first side surface of the first layer,
the first region and the third region are connected at a second reflection part provided on a second side surface of the first layer different from the first side surface,
the second region and the third region are connected to a third side surface of the first layer which is an output surface that is different from the first and second side surface,
a longitudinal direction of the first region is parallel to the output surface,
an antireflection film that reduces reflectance in a wavelength range of the light generated in the first layer is formed on the output surface,
a first light output from the second region at the output surface and a second light output from the third region at the output surface are output parallel to one another,
a distance between the fourth region and at least one of the first region, the second region, and the third region is a distance that produces evanescent coupling, and
the fourth region forms a resonator.

3. The light emitting device according to claim 1, wherein reflection surfaces are formed at ends of a longitudinal direction of the fourth region.

4. The light emitting device according to claim 1, wherein a periodic structure forming a distributed feedback (DFB) resonator is formed in the fourth region.

5. The light emitting device according to claim 1, wherein distributed Bragg reflector (DBR) resonators are formed at ends of a longitudinal direction of the fourth region.

6. The light emitting device according to claim 1, wherein the longitudinal direction of the first region and the longitudinal direction of the fourth region are parallel, and
the distance between the first region and the fourth region is a distance that produces evanescent coupling.

7. The light emitting device according to claim 1, wherein the distance between the first region and the fourth region is from 100 nm to 40 μm.

8. The light emitting device according to claim 1, wherein a plurality of the fourth regions are provided.

9. The light emitting device according to claim 8, wherein the distance between the adjacent fourth regions is from 100 nm to 40 μm.

10. The light emitting device according to claim 1, wherein the first region, the second region, the third region, and the fourth region have index guiding type structures.

11. The light emitting device according to claim 2, wherein reflection surfaces are formed at ends in a longitudinal direction of the fourth region.

12. The light emitting device according to claim 2, wherein a periodic structure forming a distributed feedback (DFB) resonator is formed in the fourth region.

13. The light emitting device according to claim 2, wherein distributed Bragg reflector (DBR) resonators are formed at ends in a longitudinal direction of the fourth region.

14. The light emitting device according to claim 2, wherein the longitudinal direction of the first region and the longitudinal direction of the fourth region are parallel, and
the distance between the first region and the fourth region is a distance that produces evanescent coupling.

15. The light emitting device according to claim 2, wherein the distance between the first region and the fourth region is from 100 nm to 40 μm.

16. The light emitting device according to claim 2, wherein a plurality of the fourth regions are provided.

17. The light emitting device according to claim 16, wherein the distance between the adjacent fourth regions is from 100 nm to 40 μm.

18. The light emitting device according to claim 2, wherein the first region, the second region, the third region, and the fourth region have refractive index waveguide-type structures.

19. A light emitting device comprising:
a multilayered structure having:
a first layer, and
a second layer and a third layer that sandwich the first layer,
the first layer having a first gain region, a second gain region, a third gain region, and a fourth gain region that generate and guide light,
the second layer and the third layer being layers that suppress leakage of the light generated in the first gain region, the second gain region, the third gain region, and the fourth gain region,
the first layer having a first surface, a second surface, and a third surface forming an outer shape of the multilayered structure,
the first surface having a first reflectance, the second surface having a second reflectance and the third surface having a third reflectance, the first reflectance being lower than the second and third reflectances in a wavelength range of the light generated in the first layer,
the first gain region being provided parallel to the first surface and providing from the second surface to the third surface as seen from a stacking direction of the multilayered structure,
the second gain region overlapping the first gain region on the second surface and provided from the second surface to the first surface,
the third gain region overlapping the first gain region on the third surface and provided from the third surface to the first surface, and
the second gain region and the third gain region being separated from each other and tilted at the same angle and connected to the first surface as seen from the stacking direction of the multilayered structure,
wherein a distance between the fourth gain region and at least one of the first gain region, the second gain region, and the third gain region is a distance that produces evanescent coupling, and
the fourth gain region forms a resonator.

20. A projector comprising:
the light emitting device according to claim 1;
a light modulation device that modulates light output from the light emitting device in response to image information; and
a projection device that projects an image formed by the light modulation device.
